(19) United States
(12) Patent Application Publication
(10) Pub. No.: US 2025/0006836 A1
(43) Pub. Date: Jan. 2, 2025

(54) SEMICONDUCTOR DEVICE WITH NITROGEN DOPED FIELD RELIEF DIELECTRIC LAYER

(71) Applicant: Texas Instruments Incorporated, Dallas, TX (US)

(72) Inventors: Jackson Bauer, Rowlett, TX (US); Yanbiao Pan, Plano, TX (US); Bhaskar Srinivasan, Allen, TX (US); Pushpa Mahalingam, Richardson, TX (US)

(21) Appl. No.: 18/344,769

(22) Filed: Jun. 29, 2023

(51) Int. Cl. H01L 29/78; H01L 21/762; H01L 29/66

(52) U.S. Cl. CPC H01L 29/7816; H01L 21/76202; H01L 29/66681

(57) ABSTRACT

Semiconductor devices including a nitrogen doped field relief dielectric layer are described. The microelectronic device comprises a substrate including a body region having a first conductivity type and a drain drift region having a second conductivity type opposite the first conductivity type; a gate dielectric layer on the substrate, the gate dielectric layer extending over the body region and the drift region and a doped field relief dielectric layer on the drift region. Doping of the field relief dielectric layer with nitrogen raises the dielectric constant of the field relief dielectric above that of pure silicon dioxide. Increasing the dielectric constant of the field relief dielectric layer may improve channel hot carrier performance, improve breakdown voltage, and reduce the specific on resistance of the microelectronic device compared to a microelectronic device of similar size with a field relief dielectric which is not doped with nitrogen.

### TECHNICAL FIELD

This disclosure relates to the field of microelectronic devices. More particularly, but not exclusively, this disclosure relates to microelectronic devices having a nitrogen doped field relief dielectric layer.

### BACKGROUND

Semiconductor components are being continually improved to reliably operate with smaller feature sizes. Fabricating semiconductor devices that have increasingly higher performance while meeting reliability specifications is challenging.

### SUMMARY

This summary is provided to introduce a brief selection of disclosed concepts in a simplified form that are further described below in the detailed description including the drawings provided. This summary is not intended to limit the claimed subject matter's scope.

Disclosed examples include a microelectronic device with a nitrogen doped field relief dielectric layer. The nitrogen doped field relief dielectric layer is a primarily silicon dioxide layer which has an atomic percent nitrogen content which may be in the form silicon oxynitride, silicon nitride, or interstitial nitrogen species or any combination thereof. The microelectronic device comprises a substrate including a body region having a first conductivity type and a drift region having a second conductivity type opposite the first conductivity type; a gate dielectric layer on the substrate, the gate dielectric layer extending over an intersection of the body region and the drift region; a field relief dielectric layer on the drift region, the field relief dielectric layer laterally abutting the gate dielectric layer at a location in the drift region, and a gate electrode on the gate dielectric layer and the field relief dielectric layer.

The doping of the field relief dielectric layer with nitrogen raises the dielectric constant of the field relief dielectric above that of pure silicon dioxide. By increasing the dielectric constant of the field relief dielectric layer, channel hot carrier performance may be improved, breakdown resistance may be improved, and specific on resistance of the microelectronic device may be lowered compared to a microelectronic device of similar size with a field relief dielectric which is not doped with nitrogen. The microelectronic device also includes a source region disposed in the body region, the source region having the second conductivity type; and a drain region disposed in the drift region, the drain region having the second conductivity type.

### BRIEF DESCRIPTION OF THE VIEWS OF THE DRAWINGS

FIG. 1A through FIG. 1L are cross sections of an example microelectronic device including a transistor with a nitrogen doped field relief dielectric layer in various stages of formation.

FIG. 2 is a top-down view of an example microelectronic device including a transistor with a nitrogen doped field relief dielectric layer.

FIG. 3 is a cross section of an alternate example microelectronic device including a transistor with a nitrogen doped field relief dielectric layer including shallow trench isolation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure is illustrated by embodiments directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to presently preferred embodiments.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to +5% to +10% variations of the recited values in some cases. In other cases, the term “approximately” may refer to +10% to +20% variations of the recited values.

Microelectronic devices are being continually improved to reliably operate with smaller feature sizes. Fabricating such microelectronic devices satisfying area scaling and reliability requirements is challenging. Certain metal-oxide-semiconductor (MOS) transistors includes features for supporting high voltage operations—e.g., with a voltage applied to their drain (or drain structure) of about 20V, 30V, 40V, or even greater. Such MOS transistors may include drain diffusion profiles (or drain junction profiles) devised to support the high voltages applied to the drain—e.g., having an extended portion to distribute the voltage drop across wider areas. Accordingly, such MOS transistors may be referred to as drain-extended MOS transistors, for example drain-extended n-channel MOS (DENMOS) transistors, drain-extended p-channel MOS (DEPMOS) transistors, laterally-diffused MOS (LDMOS) transistors, as well as groups of DENMOS and DEPMOS transistors (which may be referred to as complimentary drain-extended MOS or DECMOS transistors).

Disclosed examples include a microelectronic device with a nitrogen doped field relief dielectric layer. The nitrogen doped field relief dielectric layer is a primarily silicon dioxide layer which has an atomic percent nitrogen content which may be in the form silicon oxynitride, silicon nitride, or interstitial nitrogen species or any combination thereof. The microelectronic device comprises a substrate including a body region having a first conductivity type and a drift region having a second conductivity type opposite the first conductivity type; a gate dielectric layer on the substrate, the gate dielectric layer extending over an intersection of the body region and the drift region; a field relief dielectric layer on the drift region, the field relief dielectric layer laterally abutting the gate dielectric layer at a location in the drift region, and a gate electrode on the gate dielectric layer and the field relief dielectric layer.

The doping of the field relief dielectric layer with nitrogen raises the dielectric constant of the field relief dielectric above that of pure silicon dioxide. The increase in permittivity and dielectric constant by introducing nitrogen into the field relief dielectric layer both distributes the electric field more uniformly across the field relief dielectric layer and reduces the peak electric field near the junction of the gate dielectric and the field relief dielectric layer. This reduction of maximum electric field and more uniform distribution of electric field result in greater surface breakdown voltage of a nitrogen dope field relief dielectric layer LDMOS microelectronic device compared to a similar device with a silicon dioxide field relief dielectric layer. The improvement in surface breakdown voltage with a nitrogen doped field relief dielectric layer enables increased doping of the body region which improves body breakdown voltage with simultaneously reducing the on-resistance of the LDMOS microelectronic device with a nitrogen doped field relief dielectric layer. An added benefit of the higher dielectric constant of the nitrogen doped field relief dielectric layer is improved channel hot carrier (CHC) performance compared to a undoped field relief dielectric layer in a given device. The microelectronic device also includes a source region disposed in the body region, the source region having the second conductivity type; and a drain region disposed in the drift region, the drain region having the second conductivity type.

Described examples include doped regions of various semiconductor structures which may be characterized as p-doped and/or n-doped regions or portions, and include regions that have majority dopants of a particular type, such as n-type dopants (providing electrons as charge carriers) or p-type dopants (providing holes as charge carriers). For the purposes of this description, doping of the first type may be n-type doping (n-doped, first conductivity type) and doping of the second type may be p-type doping (p-doped, second conductivity type).

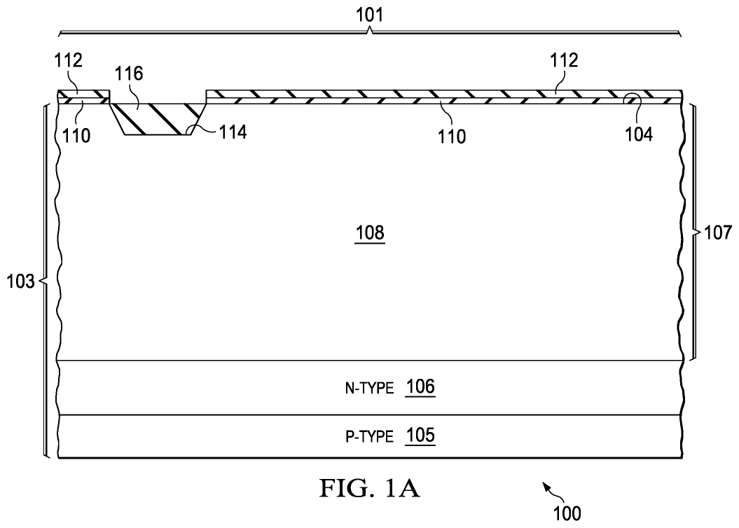

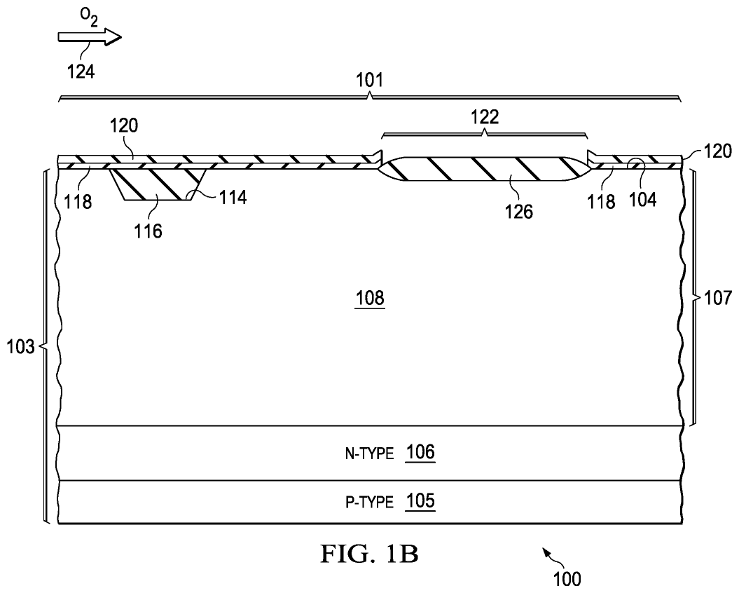

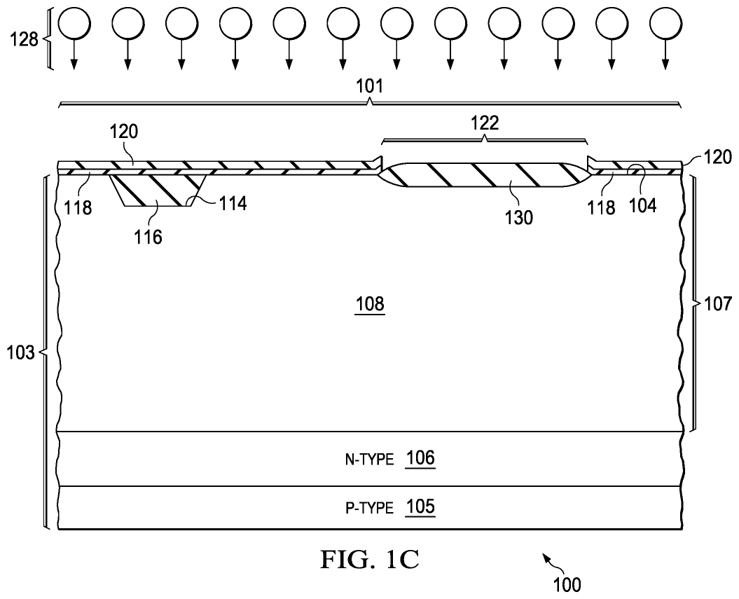

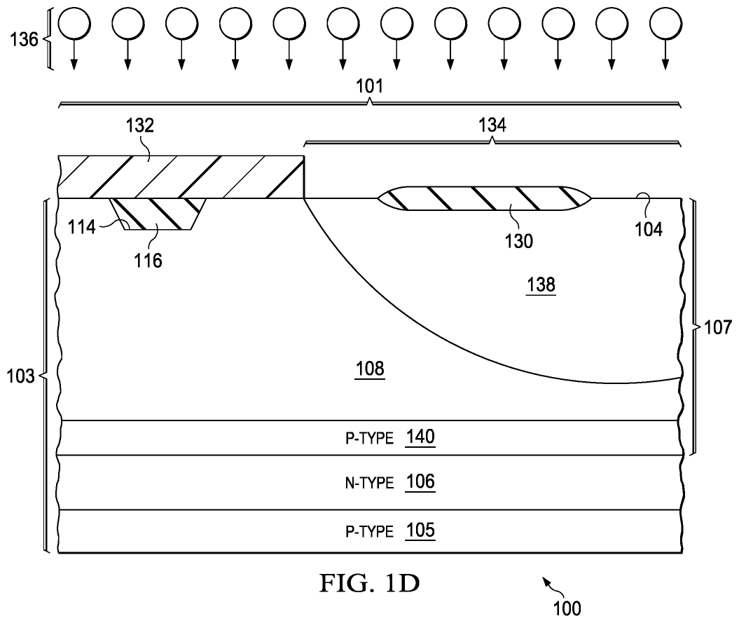

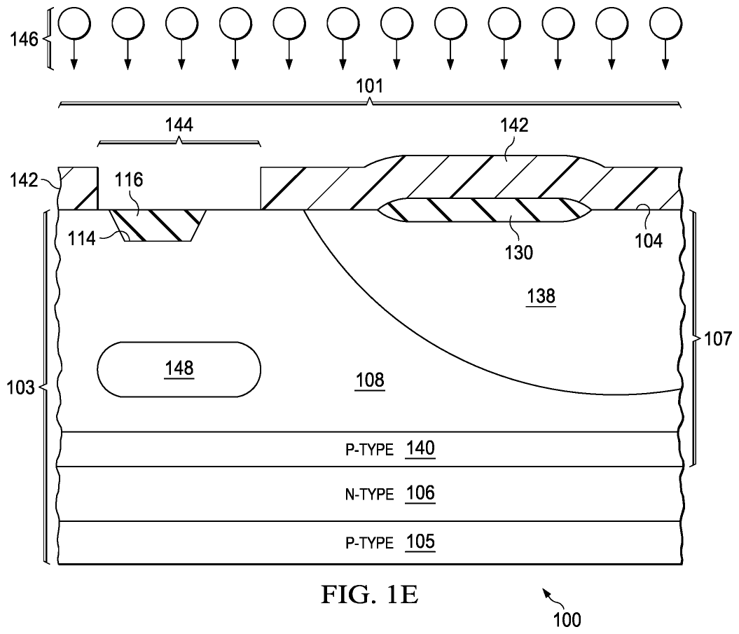

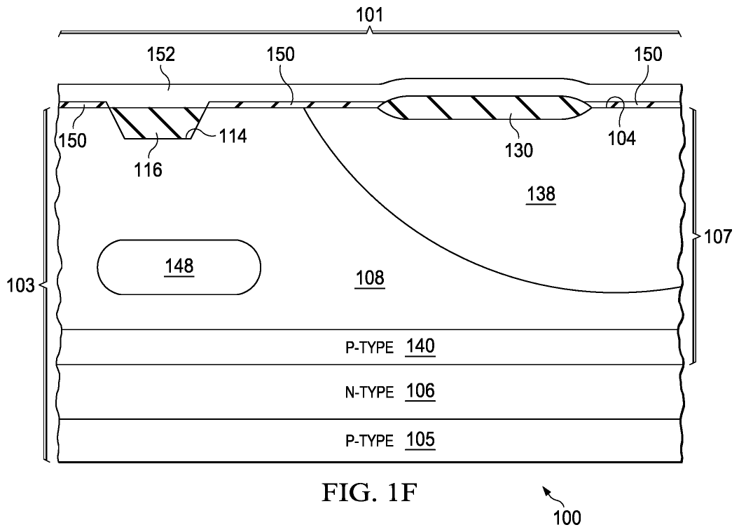

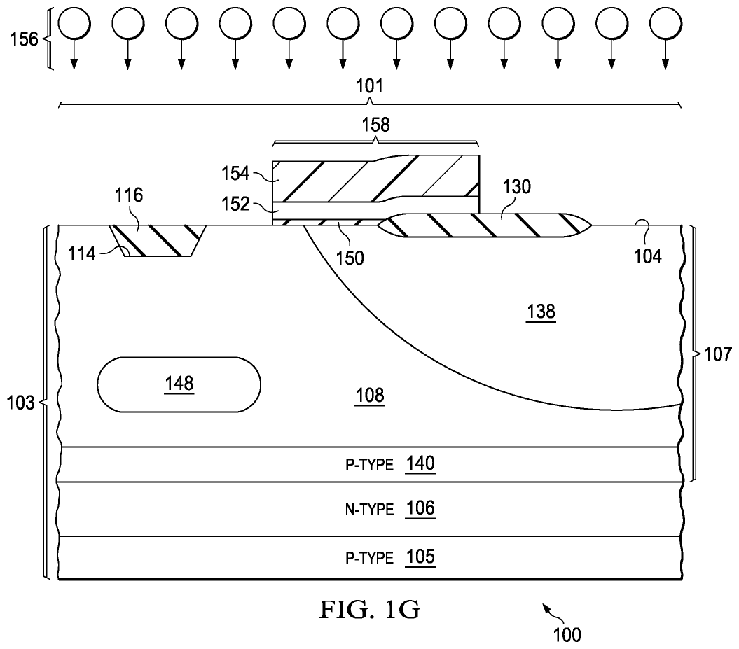

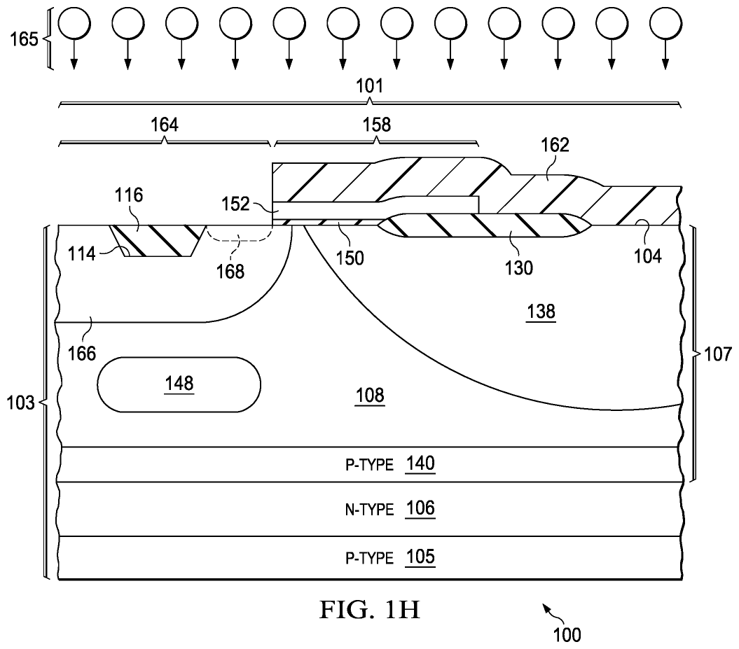

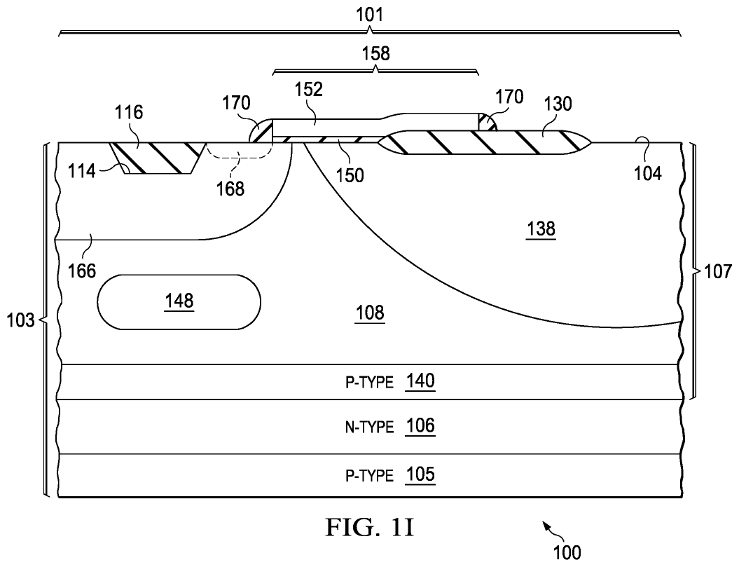

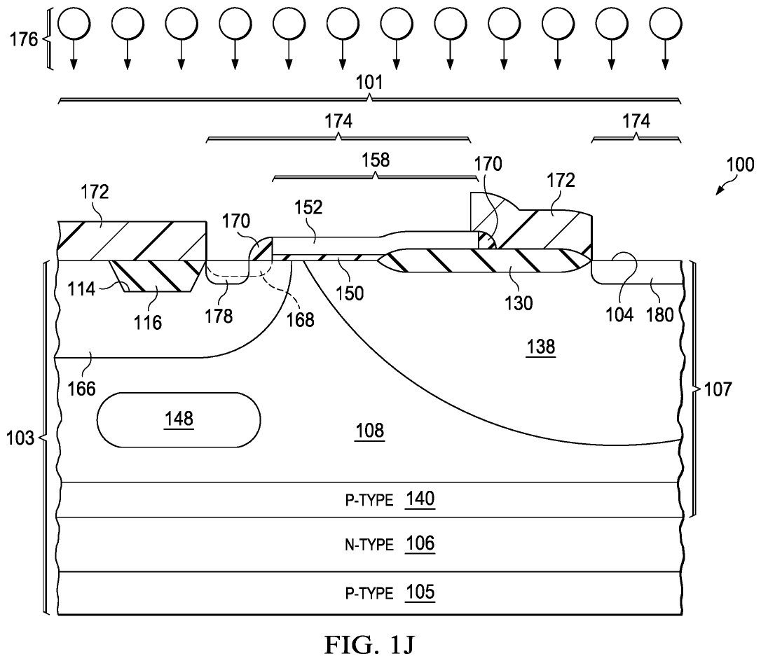

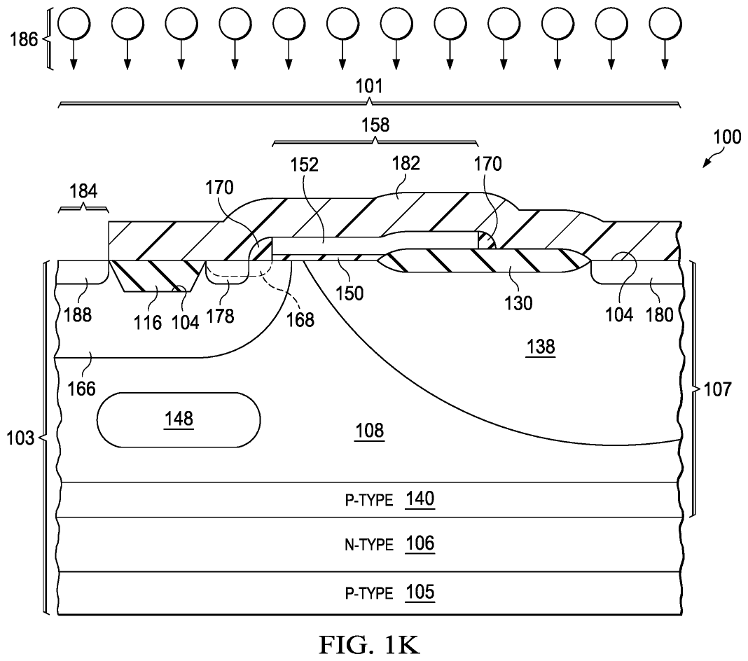

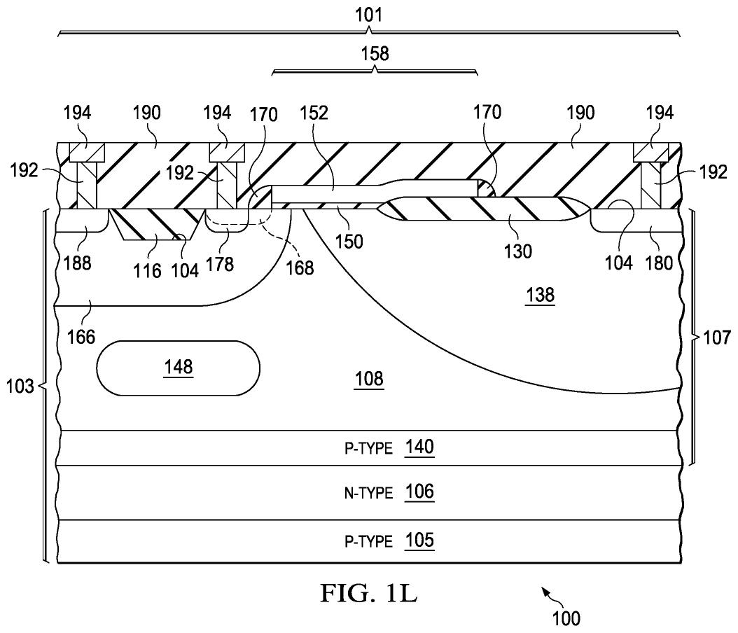

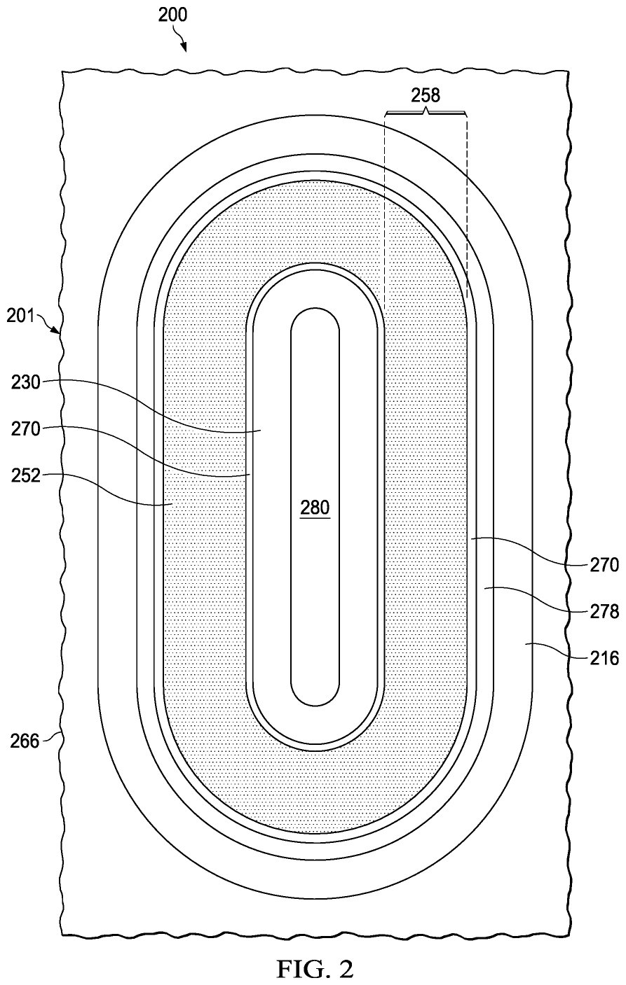

FIG. 1A through FIG. 1L are cross sections of an example microelectronic device 100 including a LDMOS transistor 101 in successive stages of an example method of formation. The LDMOS transistor 101 may have a racetrack layout (gate electrode with a closed-loop configuration) as described with reference to FIG. 2. Although the LDMOS transistor 101 described herein is an n-channel type (or an n-channel LDMOS), a p-channel type LDMOS transistor (or a p-channel LDMOS) can be formed in accordance with the present disclosure when n-doped regions are substituted by p-doped regions, and p-doped regions are substituted by n-doped regions.

FIG. 1A shows a cross section of a microelectronic device 100 which includes a base wafer 105 consisting of a semiconductor material, referred to herein as the substrate 103. The substrate 103 has a top surface 104. The base wafer 105 may be, for example, part of a bulk semiconductor wafer, part of a semiconductor wafer with an epitaxial layer, part of a silicon-on-insulator (SOI) wafer, or other structure suitable for forming the microelectronic device 100.

The base wafer 105 may include an optional n-type buried layer (NBL) 106 on a base wafer 105. The base wafer 105 may be p-type with a dopant concentration of 1×10¹⁷ atoms/cm³ to 1×10¹⁸ atoms/cm³, for example. Alternatively, the base wafer 105 may be lightly doped, with an average dopant concentration below 1×10¹⁶ atoms/cm³. The NBL 106 may be 2 microns to 10 microns thick, by way of example, and may have a dopant concentration of 1×10¹⁷ atoms/cm³ to 1×10¹⁸ atoms/cm³. The base wafer 105 may include an epitaxial layer 107 of silicon on the NBL 106. The epitaxial layer 107 is part of the substrate 103, and may be 2 microns to 12 microns thick, for example. The epitaxial layer 107 may be p-type, with a dopant concentration of 1×10¹⁵ atoms/cm³ to 1×10¹⁶ atoms/cm³, by way of example. In versions of this example in which the base wafer 105 lacks the NBL 106, the epitaxial layer 107 may be directly on the base wafer 105. As will become apparent in the discussion the epitaxial layer 107 may serve as a body region 108 of the LDMOS transistor 101. The body region 108 has a first conductivity type.

A first pad oxide layer 110 of silicon dioxide may be formed on the substrate 103. The first pad oxide layer 110 may include silicon dioxide that is formed by a thermal oxidation process or a chemical vapor deposition (CVD) process. The first pad oxide layer 110 may provide stress relief between the substrate 103 and subsequent layers. The first pad oxide layer 110 may be 5 nm to 50 nm thick, by way of example. A first silicon nitride layer 112 may then deposited and a photomask formed (not specifically shown). The photomask serves the function of masking the first silicon nitride layer 112 and it may include a light sensitive organic material that is coated, exposed, and developed. A plasma etch process (not specifically shown) removes the first silicon nitride layer 112, the first pad oxide layer 110, and the epitaxial layer 107 in an exposed region of the photomask to define a trench 114 for a shallow trench isolation (STI) field oxide region 116. The trench 114 is subsequently filled with a dielectric such as a high-density plasma (HDP) oxide (not specifically shown) followed by a chemical mechanical planarization to form the field oxide region 116 in the trench 114. A subsequent wet clean (not specifically shown) removes the first silicon nitride layer 112 and the first pad oxide layer 110 leaving the field oxide region 116 filled with dielectric. Alternatively, local oxidation of silicon (LOCOS) isolation (not specifically shown) may be substituted for the for the STI based field oxide region 116 to provide electrical isolation.

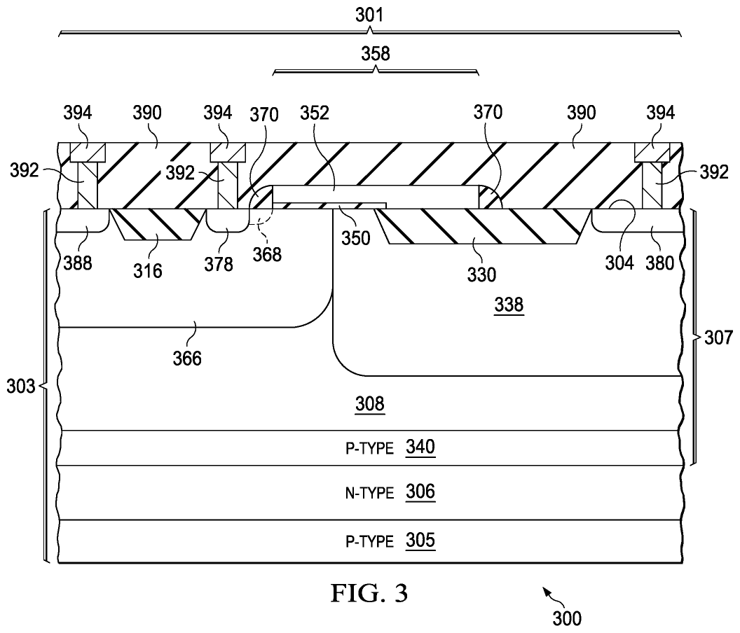

Referring to FIG. 1B, a second pad oxide layer 118 is formed on the top surface 104 and a second silicon nitride layer 120 is formed on the second pad oxide layer 118. The second silicon nitride layer 120 may be greater than 90 nm in thickness to provide an implant mask for a subsequent containing nitrogen plasma 128 step discussed in FIG. 1C. A photomask is formed (not specifically shown) which defines an open region 122. A subsequent plasma etch is used to remove the second silicon nitride layer 120 and the second pad oxide layer 118 in the open region 122 exposing the top surface 104 of the microelectronic device 100. A Local Oxidation of Silicon (LOCOS) furnace oxidation 124 may be used to form the field relief dielectric layer 126 in the open region 122. followed by a subsequent wet chemical removal (not shown) of the second silicon nitride layer 120 and the second pad oxide layer 118. In various examples the field relief dielectric layer 126 has a thickness in a range between 50 nm and 150 nm. Dielectric layers such as the field relief dielectric layer 126 derived from LOCOS type processing have a tapered edge, become thinner near their perimeter and end in a “birds beak” where the field relief dielectric layer 126 meets the epitaxial layer 107. Alternatively, the field relief dielectric layer 126 may be formed using a STI method referenced in FIG. 3. The field relief dielectric layer 126 as grown is a highly pure form of silicon dioxide (>99.99% SiO₂). The dielectric constant of the field relief dielectric layer 126 is approximately 3.9.

Referring to FIG. 1C, a nitrogen containing plasma 128 may be used which incorporates nitrogen into the field relief dielectric layer 126 of FIG. 1B to form the nitrogen doped field relief dielectric layer 130 shown in FIG. 1C. The nitrogen containing plasma 128 may contain dinitrogen (N₂), ammonia (NH₃), or other nitrogen containing precursors. The resulting nitrogen doped field relief dielectric layer 130 may contain an atomic percent nitrogen as a constituent in the form of various stoichiometries of silicon nitride (Si_{X}N_{Y}), silicon oxy nitride (Si_{X}O_{Y}N_{z}), and interstitial nitrogen either as a single component or any combination thereof. The nitrogen doping depth in the nitrogen doped field relief dielectric layer 130 may be range between 50 to 150 nm, and while the nitrogen doped field relief dielectric layer 130 is primarily silicon dioxide, it may have a nitrogen concentration greater than 20% atomic percent depending on the nitrogen containing plasma 128 formation condition. The nitrogen containing plasma 128 may result in a nitrogen doped field relief dielectric layer 130 with a uniform concentration throughout the film or a gradient of nitrogen doping, with higher doping concentration of nitrogen at the top surface of the nitrogen doped field relief dielectric layer 130 and lower concentration of nitrogen near interface between the nitrogen doped field relief dielectric layer 130 and the substrate 103. The RF power for the nitrogen containing plasma 128 may generally be between 100 W to 2000 W and may contain a RF bias plasma power of greater than 1000 W. While the dielectric constant of the field relief dielectric layer 126 (undoped) is approximately 3.9, the dielectric constant of the nitrogen doped field relief dielectric layer 130 may be greater than 5.5. It is advantageous to increase the dielectric constant by forming a nitrogen doped field relief dielectric layer 130 as the higher dielectric constant of the nitrogen doped field relief dielectric layer 130 improves the breakdown voltage, lowers specific on-resistance (when coupled with a higher doping concentration of the drain drift region 138), and improved channel hot carrier (CHC) reliability performance for a given LDMOS transistor 101 compared to a similar LDMOS transistor 101 with a field relief dielectric layer 126 which is undoped.

FIG. 1D shows a cross section after a n-drift resist 132 is deposited and patterned to form an n-drift resist opening 134. One or more n-type implants 136 are performed to form a drain drift region 138 (which may be referred to as an n-drift region) in the exposed areas of the substrate 103. The n-type implants 136 to define the drain drift region 138 may occur in multiple steps. For example, phosphorus may be implanted at a total dose of between 1×10¹² cm⁻² and 1×10¹³ cm⁻² with energies suitable for forming the drain drift region 138 with or without subsequent thermal cycles. Arsenic may also be implanted with a similar dose with an energy relatively less than the phosphorus implant. After the n-type implants 136, the n-drift resist 132 is removed.

Also referring to FIG. 1D, an optional p-type buried layer (PBL) 140 may formed using a high energy p-type implant (not specifically shown) to add p-type doping to the epitaxial layer 107. The high energy p-type implant can comprise boron at a dose from 1×10¹² cm⁻² to 1×10¹³ cm⁻² at an energy of 400 keV to 3 mega-electron volts (MeV). Indium may also be used as the implant species. For low voltage (e.g., 20 V) versions of the LDMOS transistor 101, the high energy p-type implant can be a blanket implant, while for higher voltage (e.g., >30 V) versions of the LDMOS transistor 101, the high energy p-type implant may be a masked implant to allow selective placement. For the masked implant, a photomask (not specifically shown) is deposited and patterned with an opening which exposes regions of the epitaxial layer 107 where the high energy p-type implant is to be implanted. The high energy p-type implant is followed by a thermal drive (not specifically shown) which extends the high energy p-type implant species below the drain drift region 138. The dedicated thermal drive is optional as the activation of the high energy p-type implant species may also be done during the same damage anneal as used after a n-type dwell region 168 formation discussed in FIG. 1H and after a p-type shallow well region 148 formation discussed in FIG. 1E.

Referring to FIG. 1E, a photomask 142 is deposited and patterned with a shallow p-type well opening 144 which exposes regions for a shallow p-type well implant 146 in the substrate 103 which forms the p-type shallow well region 148. The p-type shallow well implant 146 may comprise one or more implant steps, each at different energies. Body region doping provided by the p-type shallow well region 148 increases the base doping level to suppress parasitic bipolar transistor formation within the LDMOS transistor 101 and increase safe operating area (SOA).

Referring to FIG. 1F a cross section is shown after the formation of a gate dielectric layer 150 and a gate polysilicon layer 152. The gate dielectric layer 150 may be formed in a high temperature furnace operation or a rapid thermal process. Other methods of forming the gate dielectric layer 150 are within the scope of this disclosure. The thickness of the gate dielectric layer 150 may range from approximately 3 nm to 15 nm for silicon dioxide or a silicon oxynitride (SiON) gate dielectric which may be slightly thinner but with a higher dielectric constant than that of silicon dioxide, which is about 3.9, by way of example. The gate polysilicon layer 152 is formed on the gate dielectric layer 150. In some examples, the gate polysilicon layer 152 is formed by a deposition process using one or more silane-based precursors to deposit polycrystalline silicon (which may be referred to as polysilicon). In other examples, a replacement gate process may be used to form the gate polysilicon layer 152. The gate polysilicon layer 152 in this example includes polycrystalline silicon. The gate polysilicon layer 152 has a thickness that may range from approximately 50 nm to 300 nm. Moreover, the gate polysilicon layer 152 may be undoped as-deposited. Subsequently, the gate polysilicon layer 152 will be doped as described in more detail with reference to FIG. 1J.

FIG. 1G shows a cross section after a gate resist 154 has been formed and after a gate plasma etch 156. The gate plasma etch 156 removes previously formed the gate dielectric layer 150 and the gate polysilicon layer 152 in areas not covered by the gate resist 154 with the area under the gate resist 154 defining a gate electrode 158. The gate electrode 158 may have a racetrack layout (closed-loop configuration) as described with reference to FIG. 2. After the gate plasma etch 156 is complete, the gate resist 154 is removed and a wet or dry process may be used to clean the wafer surface. As shown in FIG. 1G, the gate electrode 158 extends over part of the body region 108, part of the drain drift region 138, and part of the nitrogen doped field relief dielectric layer 130 of the LDMOS transistor 101. One end of the gate electrode 158 terminates over the nitrogen doped field relief dielectric layer 130 while the opposite end of the gate electrode 158 terminates over the subsequently formed p-type well region 166 (referred to in FIG. 1H)—e.g., over the p-type well region 166 in the body region 108, which is electrically connected to the source region 178 that is formed later as depicted in FIG. 1J.

FIG. 1H shows a cross section after a p-type well resist 162 is deposited and patterned to form a p-type well resist opening 164. FIG. 1H also shows that a p-type implant 165 is performed to form a p-type well region 166 (which may be referred to as a p-well region). The p-type dopants implanted by the p-type implant 165 may include boron and/or indium. For example, a series of boron implants with an energy between 80 keV and 3 MeV, and doses between 4.0×10¹² cm⁻² to 1.5×10¹⁴ cm⁻², with a tilt angle of less than 10 degrees may be used to implant the p-type well region 166. The p-type well region 166 and the body region 108 form the body of the LDMOS transistor 101. After the p-type implant 165, the p-type well resist 162 is removed. Subsequently, a thermal process may be used to activate dopants—e.g., dopants in the drain drift region 138 and dopants in the p-type well region 166. Optionally, an n-type dopant such as arsenic or antimony can also be added to a source side of the LDMOS transistor 101 (resist pattern not shown) to form an n-type dwell region 168. For example, arsenic with a dose 5×10¹³ cm⁻² to 1.2×10¹⁵ cm⁻² (e.g., 8×10¹⁴ cm⁻²) an energy 10 keV to 50 keV (e.g., 15 keV and a 15 degree ion implant tilt angle) may be used in one particular example for the n-type dwell region 168 dopant, or some or all of this implant angled for example 45 degrees (2 or 4 rotations). The implant angle can also be straight as well (at 0 degrees) or from zero to 45 degrees.

FIG. 1I shows that a sidewall 170 may be formed on the lateral surfaces of the gate electrode 158. The sidewall 170 is formed by a blanket formation with one or more conformal layers of a dielectric material over the substrate 103 and over the gate electrode 158. The dielectric material is subsequently removed from horizontal surfaces, that is, surfaces generally parallel to the top surface 104 of the substrate 103, by an anisotropic etch process such as a reactive-ion etching (RIE) process, leaving the dielectric material on the lateral surfaces of the gate electrode 158 as the sidewall 170. The sidewall 170 may include dielectric materials such as silicon dioxide, silicon nitride, or both. The sidewall 170 may extend 50 nanometers to 200 nanometers from the lateral edge of the gate electrode 582.

FIG. 1J shows a cross section after a source and drain resist 172 is deposited and patterned. A source and drain implant 176 implants n-type dopants through source and drain resist openings 174 into the substrate 103 to form a source region 178, a drain region 180 and to provide n-type doping for the gate electrode 158. The source and drain implant 176 may occur in one or more steps with implant species including one or more of phosphorus and arsenic with an overall dose of between 5×10¹³ cm⁻² and 4.5×10¹⁵ cm⁻² and an energy between 2 keV and 80 keV. The source region 178 and drain region 180 contains an average dopant density at least twice that of the drain drift region 138 After the formation of the source region 178 and the drain region 180, the source and drain resist 172 is removed.

Referring to FIG. 1K, shows a second source and drain resist 182 is deposited and patterned to form a second source and drain resist opening 184 for a subsequent second source and drain implant 186. The second source and drain implant 186 implants p-type dopants to form the back gate region 188 of the LDMOS transistor 101. The second source and drain implant 186 also implants p-type dopants for source and drain areas in p-type channel transistors in the microelectronic device 100 (not specifically shown). The second source and drain implant 186 may occur in one or more steps with implant species including boron (or indium) with an overall dose and energy suitable to provide degenerate doping to the back gate region 188—e.g. an active average dopant density greater than 1×10¹⁹/cm³ near the solubility limit of the dopant atoms in the back gate region 188. After the second source and drain implant 186, the second source/drain resist 182 is removed.

FIG. 1L shows a cross section of the LDMOS transistor 101 after a first level of interconnects 194 is complete. In some examples, a metal silicide layer (not specifically shown) may be formed on exposed areas of the top surface 104 of the substrate 103. A pre-metal dielectric (PMD) layer 190 is formed over the top surface 104 of the substrate 103. The PMD layer 190 may include one or more dielectric layers, such as silicon nitride, silicon oxynitride, silicon dioxide, or the like. In some examples, the PMD layer 190 includes a PMD liner (not specifically shown) and a main dielectric sublayer formed on the PMD liner. Subsequently, the PMD layer 190 may be planarized by a chemical mechanical polish (CMP) process.

Contacts 192 through the PMD layer 190 may be formed. The contacts 192 may be formed by patterning and etching holes through the PMD layer 190. Contacts 192 may be filled by sputtering titanium to form a titanium adhesion layer, followed by forming a titanium nitride diffusion barrier. A tungsten core may then be formed by a process using tungsten hexafluoride (WF₆). The tungsten, titanium nitride, and titanium are subsequently removed from a top surface of the PMD layer 190 by a plasma etch process, a tungsten CMP process, or a combination of both, leaving the contacts 192 extending to the top surface of the PMD layer 190.

Interconnects 194 may be formed on the contacts 192. The contacts 192 and interconnects 194 provide electrical contact between the LDMOS transistor 101 and other components of the microelectronic device 100. In versions of this example in which the interconnects 194 have an etched aluminum structure, the interconnects 194 may be formed by depositing an adhesion layer, an aluminum layer, and an anti-reflection layer, and forming an etch mask (not explicitly shown) followed by an RIE process to etch the anti-reflection layer, the aluminum layer, and the adhesion layer where exposed by the etch mask, and subsequently removing the etch mask.

In versions of this example in which the interconnects 194 have a damascene structure, the interconnects 194 may be formed by forming an inter-metal dielectric (IMD) layer (not specifically shown) on the PMD layer 190, and etching interconnect trenches through the IMD layer to expose the contacts 192. The interconnect trenches may be filled with a barrier liner and copper. The copper and barrier liner may be subsequently removed from a top surface of the IMD layer by a copper CMP process.

FIG. 2 is a top-down view of a microelectronic device 200 including a LDMOS transistor 201 in a racetrack configuration—e.g., a racetrack layout generally having dimensions greater in a first orientation than in a second orientation perpendicular to the first orientation (or generally rectangular layouts with rounded corners). The racetrack configuration may also be referred to as a closed-loop configuration. The LDMOS transistor 201 includes aspects of the LDMOS transistor 101 described with reference to FIGS. 1A through 1L. The LDMOS transistor 201 includes a gate electrode 258 in a racetrack configuration.

As shown in FIG. 2, the drain region 280 may be singular innermost element of the LDMOS transistor 201, while the other elements shown form a series of concentric closed-loop elements around the drain region 280. The nitrogen doped field relief dielectric layer 230 abuts the drain region 280. The other elements of the LDMOS transistor 201 include the gate electrode 258, the sidewall 270, the source region 278, the field oxide region 216, and the p-type body well 266.

FIG. 3 is a cross section of an alternative microelectronic device 300 including a LDMOS transistor 301 with a nitrogen doped field relief dielectric layer 330. The LDMOS transistor 301 includes aspects of the LDMOS transistors 101 and 201 described with reference to FIGS. 1A through 1L and FIG. 2. The LDMOS transistor 301 differs from the LDMOS transistor 101 in that the nitrogen doped field relief dielectric layer 330 utilizes an STI instead of a LOCOS as a means for electrical isolation.

The nitrogen doped field relief dielectric layer 330 and the field oxide region 316 in FIG. 3 are both formed as undoped dielectric films using an STI process as discussed in FIG. 1A with respect to the formation of the field oxide region 116. Both may be formed simultaneously. As formed, both films are undoped. After the shallow trench isolation formation step referred to in FIG. 1A, a patterning step may be used to open the region over the nitrogen doped field relief dielectric layer 330 for nitrogen doping, while leaving the region over the field oxide region 316 unexposed and thus allowing the field oxide region 316 to remain undoped. In an alternate embodiment, the nitrogen doping can be formed using nitrogen precursor sources during the STI oxide deposition. A nitrogen precursor source during the STI deposition is a method to assure uniform deposition of the nitrogen dopant in the nitrogen doped field relief dielectric layer 330, though a nitrogen precursor in the source during STI deposition precludes a field oxide region 316 which is undoped in conjunction with a nitrogen doped field relief dielectric layer 330.

Also referring to FIG. 3, a p-well region 366 (which includes aspects of the p-type well region 166) is illustrated to abut a drain drift region 338 (which includes aspects of the drain drift region 138) although the present disclosure is not limited thereto. For example, the p-well region 366 may be spaced apart from the drain drift region 338 such that the epitaxial layer 307 may extend between the drain drift region 338 and the p-well region 366 to the top surface 304 of the substrate 303. Other components in the LDMOS transistor 301 include a base wafer 305, an n-type buried layer 306, an optional p-type buried layer (PBL) 340, a body region 308, a gate dielectric 350, a gate polysilicon layer 352, a gate electrode 358, an n-type dwell region 368 and sidewall 370. Additional layers include a source region 378, a drain region 380, a back gate region 388, a PMD layer 390, contacts 392 and interconnects 394.

While various embodiments of the present disclosure have been described above, it should be understood that they have been presented by way of example only and not limitation. As such, although foregoing examples are described to use various resist layers (e.g., photoresist or photomask layers) to perform various process steps (e.g., implant steps or etch steps), the present disclosure is not limited thereto. For example, one or more hard masks (including one or more layers) may be patterned to define various regions for subsequent process steps to be applied (e.g., regions for receiving dopant atoms, regions to block etchants). Moreover, the resist layers may include multi-level resists instead of a single-level resist in some examples. Numerous changes to the disclosed embodiments can be made in accordance with the disclosure herein without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A semiconductor device, comprising:
a semiconductor material of a substrate, the semiconductor material including a body region having a first conductivity type and a drain drift region having a second conductivity type;
a doped field relief dielectric layer over the drain drift region, the doped field relief dielectric layer including primarily silicon dioxide and includes at least 5 atomic percent nitrogen, the doped field relief dielectric layer extending from a gate dielectric layer toward a drain region and having a thickness greater than the gate dielectric layer; wherein the gate dielectric layer over the body region extends over an intersection between the body region and the drain drift region;
a gate electrode over the gate dielectric layer; and
a drain region having the second conductivity type contacting the drain drift region, the drain region having an average dopant density greater than an average dopant density of the drain drift region.

2. The semiconductor device of claim 1, wherein the doped field relief dielectric layer includes a local oxidation of silicon (LOCOS) layer of silicon dioxide including at least 5 atomic percent nitrogen and including a tapered edge.

3. The semiconductor device of claim 1, wherein the doped field relief dielectric layer includes a shallow trench isolation (STI) layer of silicon dioxide including at least 5 atomic percent nitrogen.

4. The semiconductor device of claim 1 wherein a portion of an atomic percent nitrogen in the doped field relief dielectric layer is a constituent of silicon nitride.

5. The semiconductor device of claim 1 wherein a portion of an atomic percent nitrogen in the doped field relief dielectric layer is a constituent of silicon oxynitride.

6. The semiconductor device of claim 1, wherein the first conductivity type is p-type and the second conductivity type is n-type.

7. The semiconductor device of claim 1, wherein an atomic percent nitrogen of the doped field relief dielectric layer is more concentrated at a top surface of the doped field relief dielectric layer than at an interface between the doped field relief dielectric layer and the substrate.

8. The semiconductor device of claim 1, wherein an atomic percent nitrogen of the doped field relief dielectric layer has an approximately uniform concentrated of atomic percent nitrogen throughout doped field relief dielectric layer.

9. The semiconductor device of claim 1, wherein the gate electrode has a closed-loop configuration.

10. The semiconductor device of claim 1 wherein a doped field oxide includes at least 5 atomic percent nitrogen.

11. A method of forming a microelectronic device, comprising:
forming a body region and a drain drift region in a semiconductor material of a substrate, the body region having a first conductivity type and the drain drift region having a second conductivity type;
forming a doped field relief dielectric layer over the drain drift region, the doped field relief dielectric layer having greater than 5 atomic percent nitrogen and a thickness greater than a gate dielectric layer;
forming the gate dielectric layer over the body region, the gate dielectric layer extending over an intersection between the body region and the drain drift region;
forming a gate electrode over the gate dielectric layer;
forming a source region having the second conductivity type contacting the body region, the source region having an average dopant density greater than the average dopant density of the body region; and
forming a drain region having the second conductivity type contacting the drain drift region, the drain region having an average dopant density greater than an average dopant density of the drain drift region.

12. The method of claim 11, wherein a field relief dielectric layer is formed by local oxidation of silicon (LOCOS).

13. The method of claim 11, wherein a field relief dielectric layer is formed by shallow trench isolation (STI).

14. The method of claim 11, wherein a doped field relief dielectric layer is formed by a nitrogen containing plasma including dinitrogen (N2) which incorporates an atomic percent nitrogen into a field relief dielectric layer.

15. The method of claim 11, wherein a dope field relief dielectric layer is formed by a nitrogen containing plasma including ammonia (NH3) which incorporates an atomic percent nitrogen into a field relief dielectric layer.

16. The method of claim 11, wherein a doped field relief dielectric layer is formed by a dielectric deposition process including at least one nitrogen containing precursor.

17. The method of claim 11, wherein the doped field relief dielectric layer and a doped field oxide layer are formed concurrently.

18. The method of claim 11, wherein a portion of an atomic percent nitrogen in the doped field relief dielectric layer is formed by a nitrogen containing plasma as silicon nitride.

19. The method of claim 11 wherein a portion of an atomic percent nitrogen in the doped field relief dielectric layer is formed by a nitrogen containing plasma as silicon oxynitride.

20. The method of claim 11, wherein an atomic percent nitrogen of the doped field relief dielectric layer is formed with a higher concentration of nitrogen at a top surface of the doped field relief dielectric layer than at an interface between the doped field relief dielectric layer and the substrate.
